(19) United States
(12) Patent Application Publication
(10) Pub. No.: US 2009/0298225 A1
(43) Pub. Date: Dec. 3, 2009

(54) Doped Metal Oxide Films and Systems for Fabricating the Same

(76) Inventors: Ping Wu, Singapore (SG); Hao Gong, Singapore (SG); Zhi Gen Yu, Singapore (SG)

Correspondence Address: QUARLES & BRADY LLP, 33 E. MAIN ST, SUITE 900, P.O BOX 2113, MADISON, WI, 53701-2113, US

(21) Appl. No.: 11/719,741

(22) PCT Filed: Nov. 18, 2005
(86) PCT No.: PCT/SG2005/000393

§ 371 Date: Jun. 18, 2009

Related U.S. Application Data
(60) Provisional application No. 60/629,596, filed on Nov. 19, 2004.

(51) Int. Cl. H01L 21/365; C23C 16/40; C23C 16/52

(52) U.S. Cl. 438/104; 118/723 R; 257/E21.463

(57) ABSTRACT

A method of fabricating a doped metal oxide film comprising the steps of: (a) providing a semiconductor substrate in a vacuum chamber; (b) generating plasma comprising at least metal (M) , oxygen (O) and dopant ions within said chamber in the presence of an inert carrier gas; (c) forming a doped metal oxide (MO) film on said substrate from said plasma; and (d) controlling, during step (c) , the amount of O ions relative to said dopant ions within said plasma to form at least one of an n-type MO film and a p-type MO film on said substrate. A system for fabricating the doped metal oxide is also disclosed.

### TECHNICAL FIELD

The present invention relates to methods of fabricating doped metal oxide films and to systems for fabricating the same.

### BACKGROUND

Transparent conducting oxides (TCOs), such as zinc oxide, indium oxide, tin oxide, indium tin oxide, cadmium oxide and indium cadmium oxide, are wide gap semiconductors that are commonly used in optoelectronic devices such as light emitting diodes (LEDs) and lasers operating in the blue region of the colour spectrum. However, fabricating a p-n homojunction using wide-gap semiconductors is faced with problems as they either form n-type or p-type but not both types.

It was found that by doping wide-gap semiconductors with different types of dopant sources, each dopant source containing the same dopant element, may result in formation of both p-type and n-type semiconductors. For example, for a nitrogen (dopant element) doped Zinc Oxide (ZnO) film, using N₂ as the dopant source led to n-type conduction whilst using NO₂ or NO as the dopant source led to p-type conduction, and using P₂O₅ as the dopant source led to n-type conduction whilst Zn₃P₂ led to p-type conduction.

Physical vapour deposition methods such as magnetron sputtering have been used to fabricate doped metal oxide films. Such methods involve radio frequency (RF) sputtering of one or more targets comprising the metal oxide and the dopant source within a vacuum chamber to deposit a doped metal oxide film on a substrate. Accordingly, in order to produce a semiconductor having a p-n homojunction, i.e., a layer of n-type metal oxide film and a layer of p-type metal oxide film, two separate chambers, each equipped with target materials comprising the respective dopant material, are required for forming the n-type and p-type metal oxide films. Accordingly, the substrate will have to be transferred from one chamber to another after deposition which can be tedious and time consuming.

The development of optoelectronic devices requires high quality p-type and n-type metal oxide films. A p- and n-type doped metal oxide film that is of at least the same quality or better quality than existing films may usefully be provided.

There is therefore a need to provide a method and system for fabricating doped metal oxide films that overcome or at least ameliorate one or more of the disadvantages described above.

### SUMMARY OF INVENTION

According to a first aspect of the invention, there is provided a method of fabricating a doped metal oxide film comprising the steps of:
(a) providing a semi-conductor substrate in a vacuum chamber;
(b) generating plasma comprising at least metal (M) , oxygen (O) and dopant ions within said chamber in the presence of an inert carrier gas;
(c) forming a doped metal oxide (MO) film on said substrate from said plasma; and
(d) controlling, during step (c) , the amount of O ions relative to said dopant ions within said plasma to form at least one of an n-type MO film and a p-type MO film on said substrate.

According to a second aspect of the invention, there is provided a system for fabricating a doped metal oxide (MO) film comprising:

a vacuum chamber having a mount for mounting a semi-conductor substrate therein;

a plasma generator capable of generating plasma from one or more targets, said plasma comprising at least metal (M), oxygen (O) and dopant ions;

at least one gas conduit for supplying gas into said chamber;

a controller for controlling the supply of said gas to said chamber and for controlling said plasma generator;

wherein in use, a semi-conductor substrate is mounted on said mount and an inert carrier gas is supplied to said chamber via said gas conduit, and wherein said controller operates said plasma generator to form plasma comprising at least metal (M), oxygen (O) and dopant ions to form a doped MO film layer on said mounted substrate, and wherein the amount of O ions relative to M ions within said plasma is controlled to form at least one of an n-type MO film and a p-type MO film on said substrate.

According to a third aspect of the invention, there is provided a method of fabricating a phosphorous-doped zinc oxide (ZnO) film comprising the steps of:

(a) providing a semiconductor substrate in a vacuum chamber;

(b) generating plasma comprising at least zinc (Zn) , oxygen (O) and phosphorous (P) ions within said chamber in the presence of an inert carrier gas;

(c) forming a phosphorous doped ZnO film layer on said substrate from said plasma; and

(d) controlling, during step (c) , the amount of O ions relative to Zn ions within said plasma to form at least one of an n-type ZnO film and a p-type ZnO film on said substrate.

According to a fourth aspect of the invention, there is provided a system for fabricating a phosphorous-doped zinc oxide (ZnO) film comprising:

a vacuum chamber having a mount for mounting a semi-conductor substrate therein;

a plasma generator capable of generating plasma from one or more targets, said plasma comprising at least zinc (Zn), oxygen (O) and phosphorous (P) ions;

at least one gas conduit for supplying gas into said chamber;

a controller for controlling the supply of said gas to said chamber and for controlling said plasma generator;

wherein in use, a semi-conductor substrate is mounted on said mount and an inert carrier gas is supplied to said chamber via said gas conduit, and wherein said controller operates said plasma generator to form plasma comprising at least zinc (Zn), oxygen (O) and phosphorous (P) ions to form a phosphorous doped ZnO film layer on said mounted substrate, and wherein the amount of O ions relative to Zn ions within said plasma is controlled to form at least one of an n-type ZnO film and a p-type ZnO film on said substrate.

### Definitions

Unless specified otherwise, the terms “comprising” and “comprise”, and grammatical variants thereof, are intended to represent “open” or “inclusive” language such that they include recited elements but also permit inclusion of additional, unrecited elements.

As used herein, the term “about”, typically means +/−5% of the stated value, more typically +/−4% of the stated value, more typically +/−3% of the stated value, more typically, +/−2% of the stated value, even more typically +/−1% of the stated value, and even more typically +/−0.5% of the stated value.

Throughout this disclosure, certain embodiments may be disclosed in a range format. It should be understood that the description in range format is merely for convenience and brevity and should not be construed as an inflexible limitation on the scope of the disclosed ranges. Accordingly, the description of a range should be considered to have specifically disclosed all the possible sub-ranges as well as individual, numerical values within that range. For example, description of a range such as from 1 to 6 should be considered to have specifically disclosed sub-ranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

### DETAILED DISCLOSURE OF EMBODIMENTS

Exemplary, non-limiting embodiments of a method of fabricating a doped metal oxide film and a system for fabricating the same, will now be disclosed.

The method of fabricating a doped metal oxide (MO) film comprises the steps of:

(a) providing a semiconductor substrate in a vacuum chamber;

(b) generating plasma comprising at least metal (M) , oxygen (O) and dopant ions within said chamber in the presence of an inert carrier gas;

(c) forming a doped metal oxide (MO) film on said substrate from said plasma; and

(d) controlling, during step (c), the amount of O ions relative to said dopant ions within said plasma to form at least one of an n-type MO film and a p-type MO film on said substrate.

The system for fabricating a doped metal oxide (MO) film comprises:

a vacuum chamber having a mount for mounting a semi-conductor substrate therein;

a plasma generator capable of generating plasma from one or more targets, said plasma comprising at least metal (M), oxygen (O) and dopant ions;

at least one gas conduit for supplying gas into said chamber;

a controller for controlling the supply of said gas to said chamber and for controlling said plasma generator;

wherein in use, a semi-conductor substrate is mounted on said mount and an inert carrier gas is supplied to said chamber via said gas conduit, and wherein said controller operates said plasma generator to form plasma comprising at least metal (M), oxygen (O) and dopant ions to form a doped MO film layer on said mounted substrate, and wherein the amount of O ions relative to M ions within said plasma is controlled to form at least one of an n-type MO film and a p-type MO film on said substrate.

The vacuum chamber may be maintained at a pressure range selected from the group consisting of: 100 mPa to 7,000 mPa, 100 mPa to 5,000 mPa, 100 mPa to 4,000 mPa, 100 mPa to 3,000 mPa, 100 mPa to 2,000 mPa, 500 mPa to 7,000 mPa, 1000 mPa to 7,000 mPa, 2000 mPa to 7,000 mPa, and 3000 mPa to 7,000 mPa.

### Semiconductor Substrate

The semiconductor substrate can be made from any semiconductor material such as zinc oxide, aluminum oxide, silicon or glass.

In one embodiment, the substrate is silicon. Advantageously, silicon has good processability and is relatively cheap when compared to the other semiconductor materials.

In another embodiment, the substrate is zinc oxide. Advantageously, ZnO is suitable for growing thin films of doped metal oxide owing to its excellent match with the doped metal oxide film in terms of thermal expansion and crystalline structure.

The semiconductor substrate, during the forming step (c), may be maintained at a temperature range selected from the group consisting of: 200° C. to 500° C., 300° C. to 500° C., 400° C. to 500° C., 200° C. to 400° C. and 200° C. to 300° C.

### Metal Oxide

The metal oxides can be transparent conducting oxides (TCOs) such as zinc oxide, indium oxide, tin oxide, indium tin oxide, cadmium oxide and indium cadmium oxide.

In one embodiment, the metal component of the metal oxide may be selected from Group IIB (such as zinc and cadmium) or Group III (such as gallium and indium) of the Periodic Table of Elements. In another embodiment, the metal component of the metal oxide is zinc. Advantageously, ZnO has a high exciton energy (60 meV) which renders it suitable for use in optoelectronic devices.

### Dopant

The dopant may be selected from Group I (such as lithium, sodium and potassium) or Group V (such as nitrogen, arsenic and phosphorous) of the Periodic Table of Elements. In a preferred embodiment, the dopant may be Phosphorous (P).

The dopant can be delivered into the metal oxides in the form of compounds containing the dopant element. For example, dopant sources for P include Zn₃P₂ and P₂O₅, and dopant sources for N include N₂, NO₂ and NO.

### Target Material

One or more target materials can be provided within the chamber to generate at least M, O and dopant ions within the plasma. The target material can be selected from at least one of M, MO and dopant material.

The target materials can also be provided within the chamber to generate at least Zn, O and P ions within the plasma. The target material, in this case, can be selected from at least one of Zn, P, ZnO, P₂O₅ and Zn₃P₂.

There can be one single target within the chamber or a plurality of targets within the chamber. The single target may comprise a plurality of target materials sintered together, for example, the materials ZnO and P₂O₅ can be sintered into a single target for magnetron sputtering to generate Zn, O and P ions.

The target can also be in the form of separate targets, each of a target material selected from the above, for example, a first target comprising pure ZnO and a second target comprising a mixture of ZnO and P₂O₅ sintered together.

The target materials within said chamber can have a higher molar ratio of M atoms or Zn atoms relative to O atoms. The molar ratio of M atoms or Zn atoms relative to O atoms in said target materials can be selected from the group consisting of: about 1.01:1, about 1.05:1, about 1.1:1, about 1.2:1, about 1.5:1, about 2:1, about 3:1, about 2.01:3, about 2.05:3, about 2.1:3, about 2.2:3, about 2.5:3, about 3:3 and about 4:3.

### Controller

The controller controls the supply of said gas to said chamber and controls said plasma generator.

In one embodiment, the controller regulates the flow of oxygen gas into said chamber in controlling step (d). Additionally, the controller can also regulate the flow of inert gas carrier into said chamber.

The flow of the gases into said chamber can be regulated by a mass flow controller or a pressure flow controller. An example of a suitable mass flow controller is a MKS Type 247D model by MKS Instruments.

The controller may also comprise a RF power controller for controlling the RF power of sputtering to the targets to control the generation of plasma. The RF power of the sputtering can be in the range of 0-600 Watts. An example of a suitable RF power controller is a RFG 600 SE model by Coaxial Power System Ltd.

The amount of oxygen gas by volume in the chamber, in the regulating step (d1), may be in the range selected from the group consisting of 0% to less than 7%, 0% to 3%, 0% to 2%, 0% to 1%, 3% to 6%, 3% to 5%, and 3% to 4%.

To form n-type MO film or ZnO film, the amount of oxygen within said chamber can be maintained at the range between 0% to 3% by volume in the regulating step (d1).

To form p-type MO film or ZnO film, the amount of oxygen within said chamber can be maintained at the range between 3% to less than 7% by volume in the regulating step (d1).

The volume ratio of oxygen gas to inert carrier gas in the chamber may be in the range selected from the group consisting of: 5:95 to 20:80, 5:95 to 15:85, 5:95 to 10:90, 10:90 to 20:80, and 15:85 to 20:80.

Advantageously, both an n-type MO film and a p-type MO film can be fabricated to form a p-n junction within the same chamber using the same dopant source simply by varying the amount of oxygen within the chamber.

### BRIEF DESCRIPTION OF DRAWINGS

The accompanying drawings illustrate a disclosed embodiment and serves to explain the principles of the disclosed embodiment. It is to be understood, however, that the drawings are designed for purposes of illustration only, and not as a definition of the limits of the invention.

FIG. 1 shows a schematic view of an apparatus for fabricating a phosphorous-doped zinc oxide (ZnO) film using a method in accordance with a disclosed embodiment (MSS3A sputtering system).

FIG. 2 shows a phase diagram of a Zn—O—P ternary system.

FIG. 3 shows the energy levels of P-doped ZnO in ZnO:P₂O₅ and ZnO:Zn₃P₂ systems.

FIG. 4 shows the current (I)—voltage (V) characteristics of (a) p-type ZnO and (b) p-n homojunction formed from p-type and n-type ZnO.

FIG. 5 shows a schematic diagram of a LED based on P doped ZnO p-n homojunction.

FIG. 6 shows a luminance spectra of ZnO p-n homojunction loaded forward bias (20V) at room temperature.

### BEST MODE

Non-limiting examples of the invention, including the best mode, and a comparative example will be further described in greater detail by reference to specific Examples, which should not be construed as in any way limiting the scope of the invention.

### EXAMPLE 1

Preparation of p-type and n-type Phosphorous (P) Doped Zinc Oxide (ZnO) Film Using P₂O₅ as Dopant Source.

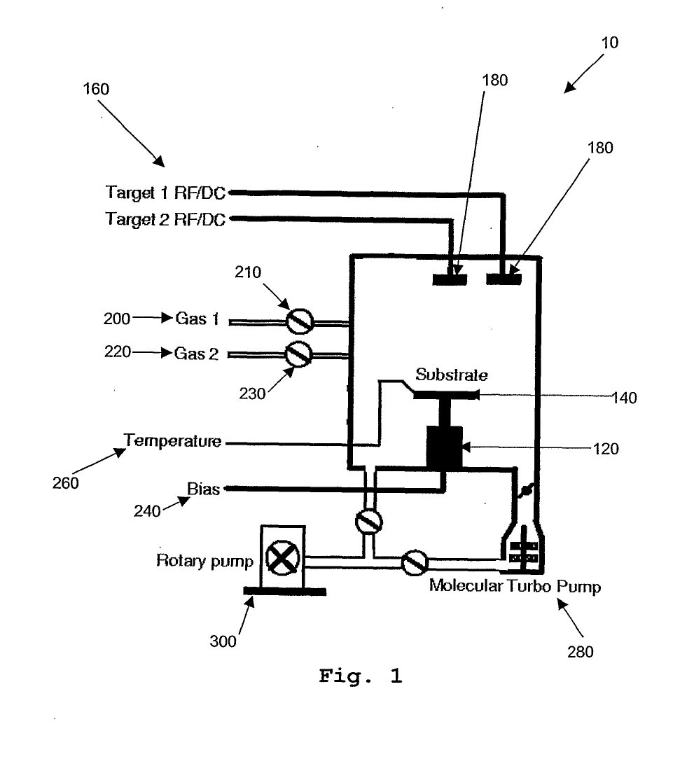

A system 10 for fabricating P-doped ZnO film by physical vapour deposition (PVD) is shown in FIG. 1. The system is a radio frequency (RF) magnetron sputtering system (coaxial MSS3A/LL).

The system comprises a vacuum chamber 100 having a mount 120 for mounting a silicon substrate 140 therein, a RF magnetron sputter 160 for generating plasma from a target 180, gas conduits 200,220 for supplying Ar and O₂ gases respectively into the chamber 100, and mass flow controllers 210,230 for controlling the supply of Ar and O₂ gases respectively into the chamber 100. A RF power controller (Model: RFG 600 SE by Coaxial Power System Ltd) (not shown in the FIGS.) for controlling RF power of the RF magnetron sputter is also provided.

The silicon substrate 140 is an n-type semiconductor substrate and is pre-sputtered with a 100 nm layer of pure ZnO. The mount 120 rotates the substrate 140 during the deposition process to achieve a uniform coating. The substrate 140 is biased by a biasing voltage 240 provided by the RF power. The substrate 140 is connected to a heater 260 to control the temperature of the substrate 140 during deposition. The substrate is placed at a distance of 100 mm beneath the target 180. The target 180 comprises a mixture of ZnO powder (95 wt %) and P₂O₅ powder (5 wt %) sintered together. A rotary pump 300 is connected to the chamber and to a molecular turbo pump 280. The rotary pump 300 provides an initial vacuum within the chamber while the molecular turbo pump 280 provides a further vacuum within the chamber to achieve the desired working pressure. The total working pressure in the chamber 100 was maintained at 15 mTorr (2000 mPa). The power of the RF magnetron sputtering on the target 180 was maintained at 40 W, and the frequency at 13.6 MHz.

Prior to deposition, the substrate 140 was rotated and the target 180 was sputtered for 20 minutes to clean its surface at a RF power of 40 W.

Thereafter, deposition of p doped ZnO film commenced as the target was sputtered at the conditions described above. The sputtering results in the formation of a plasma comprising Zn, O and P ions in the presence of Argon gas. During deposition, the argon gas carries the Zn, P and O ions to the surface of the substrate to form the P doped ZnO film. The temperature of the substrate was maintained at 300° C.

O₂ gas is supplied into the chamber and regulated to maintain a percentage by volume of 5% for a time period of 10 minutes in the chamber to grow 400 nm layer of p-type ZnO film on the substrate.

Thereafter, the oxygen supply is cut off and the target was sputtered for 100-120 minutes under the same conditions to deposit 400 nm layer of n-type P doped ZnO substrate on the p-type ZnO film.

As the flow of gases into the chamber are regulated by a mass flow controller, it will be necessary to convert the volume percentage O₂ gas into mass units when setting the massing flow controller to supply a selected volume percent of gas into the chamber. An exemplary calculation is shown below.

A 3% volume O₂ in a 1 m³ chamber at standard state (1 atmosphere and 25° C.), having a residence time of 1 hour:

Molar volume of O₂: 17.36×10⁻⁶ m³/mol

Molar mass of O₂: 32.00 g/mol

Volume flow rate of 3% O₂ in the chamber: 0.03 m³/h

Therefore, molar flow rate of O₂ to be supplied to the chamber=

0.03 m³/h/17.36×10⁻⁶ m³/mol=1728.1 moles/h

Mass flow rate of O₂ to be supplied to the chamber=

1728.1 moles/h×32.00 g/mol=55299.2 g/h (55.3 kg/h)

It should be noted that like all gases, the molar volume of O₂ gas is dependent on temperature and pressure. When performing the above calculation, the values of molar volume of oxygen gas at the selected temperature and pressure can be obtained from textbooks/handbooks providing such information. (Such textbooks/handbooks include “Vacuum physics and techniques”/By T. A. Delchar. London; New York : Chapman & Hall, 1993. 1^{st} edition.

### EXAMPLE 2

Preparation of p-type and n-type Phosphorous (P) Doped Zinc Oxide (ZnO) Film Using Zn₃O₂ as Dopant Source.

The P doped ZnO film is deposited using the same method and conditions described in Example 1. However, in this Example, the two targets were employed—pure ZnO target and pure Zn₂P₃ targets 180, both sputtered at RF powers of 40 W and 15 W respectively.

### EXAMPLE 3

### Zn—O—P Ternary System

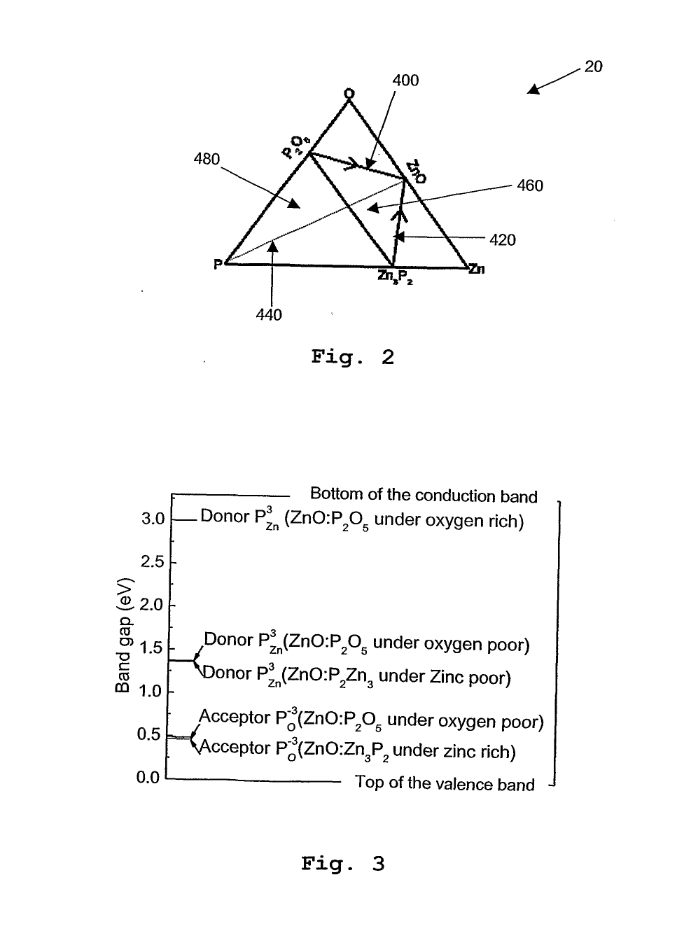

The possible doping sources for ZnO include Zn₃P₂, P₂O₅ and P. In a Zn—O—P ternary system 20 as shown in FIG. 2, phosphorus doping in ZnO can be carried out either along the ZnO—P₂O₅ binary 400 or the ZnO—Zn₃P₂ binary 420. P—ZnO binary 440 is not stable as it either belongs to a ZnO—P₂O₅—Zn₃P₂ ternary 460 or a P—P₂O₅—Zn₃P₂ ternary 480 depending on the phosphorus concentration. Accordingly, only ZnO—P₂O₅ system and ZnO—Zn₃P₂ system and the dopant behaviours of P₂O₅ (under both oxygen rich and oxygen poor)and Zn₃P₂ (under both oxygen rich and oxygen poor) were investigated.

The dopant sources were optimized and the possible acceptor and donor levels predicted theoretically.

To optimize the dopant source for P-doped ZnO, a density functional theory (DFT) calculation using CASTEP code was employed. Oxygen rich (zinc poor) and oxygen poor (zinc rich) conditions for the ZnO—P₂O₅ system and ZnO—Zn₃P₂ systems were used to analyse formation energies of P with all possible charged interstitial and substitutional states. The energy levels of P in ZnO forbidden gap are shown in FIG. 3.

For the system of ZnO—P₂O₅, P is a donor which is located at 0.3 eV below the bottom of conduction band under the oxygen rich growth conditions.

Under the oxygen rich growth condition, a possible acceptor level at 0.49 eV above the top of valence band is also formed if the substitutions at zinc sites are suppressed.

Otherwise, a deep donor at 1.37 eV above the top of valence band would be more stable, which makes p-type conduction unstable.

For the system of ZnO—Zn₃P₂ using Zn₃P₂ as the dopant source, a shallow acceptor at 0.47 eV above the top of valence band under the zinc rich condition is obtained, but a deep donor at 1.37 eV above the top of valence band is formed under the zinc poor condition.

For all doping systems, the thermal (or temperature) effect was considered by employing commercial a thermochemistry software, FACTSage. Based on the calculation results, it was found that the thermal effect becomes the winning factor for the shallow acceptor only in the ZnO:Zn₃P₂ doping system under zinc rich growth condition at an elevated temperature (400° C.).

In summary, theoretical calculations predict that n-type ZnO will normally be obtained when P₂O₅ is used as the dopant source, n-type ZnO will be obtained under the zinc poor condition, and p-type ZnO can be achieved under zinc rich condition when Zn₃P2 is employed as the dopant source.

To investigate the above theoretical prediction, P₂O₅ and Zn₃P₂ in the Zn—O—P system are employed as dopant sources during the deposition of ZnO films. The ZnO films are deposited using the methods of Examples 1 and 2.

After studying the various film growth conditions, it was found that P doped ZnO thin films exhibit n-type conduction in the ZnO:P₂O₅ system and in the ZnO:Zn₃P₂ doping system under oxygen poor condition. However, with control of growth conditions; p-type conductivity of the ZnO:Zn₃P₂ system under the zinc rich condition is achieved. The experimental results match the theoretical prediction.

I-V characteristic of p-type ZnO vs n-type Si substrate, p-type ZnO vs. n-type ZnO are shown in FIG. 3. P doped ZnO samples under the ZnO:P₂Zn₃ system displayed good rectification behaviour. The Hall coefficient of +0.406 cm³C⁻¹, measured by van der Pauw electrode configuration, suggested the conduction to be p-type. Combining the Hall coefficient and conductivity measurement resulted in a carrier density of 3.84×10¹⁹ cm⁻³, Hall mobility of the positive holes of 6.69 cm²V⁻¹s⁻¹ and the resistivity of 0.024 Ohm.cm. The Seebeck coefficient was found to be positive, further confirming p-type conductivity. The X-ray powder diffraction patterns of ZnO:P thin films deposited by the two doping systems showed a strong peak at 34.4325° (2θ) consistent with c-axis oriented wurtzite ZnO.

It is very interesting that the same element (P) can create either p-type or n-type conduction of ZnO using different dopant sources containing the same dopant element. Furthermore, p- and n-type P doped ZnO thin films can be obtained by adjusting the oxygen concentration during sputtering in the ZnO:Zn₃P₂ system. This will make fabrication of ZnO p-n junction devices very convenient and cheap, as the same deposition chamber and the same dopant source are used for both purposes.

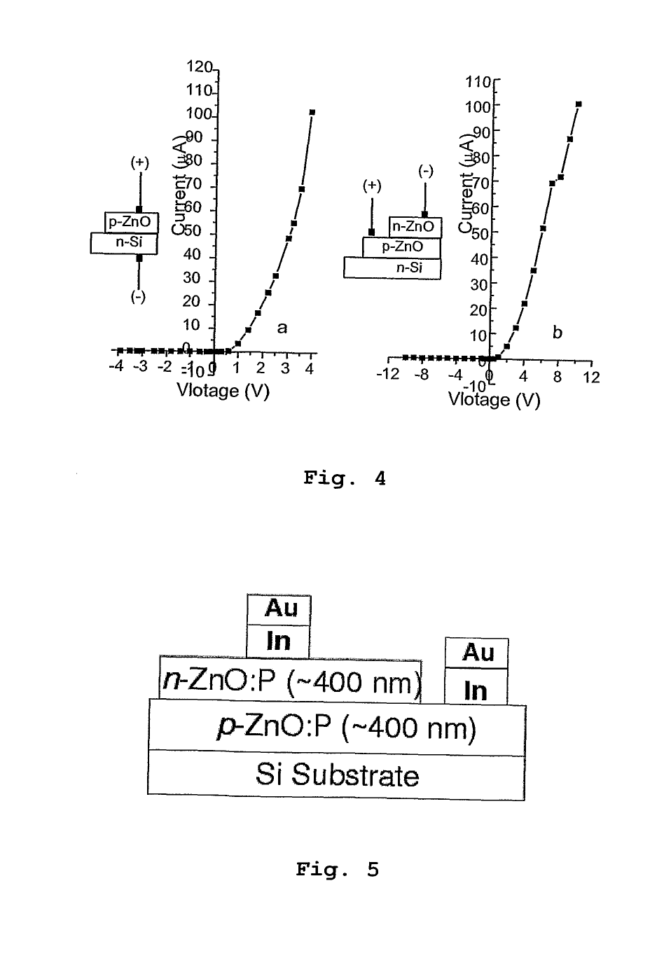

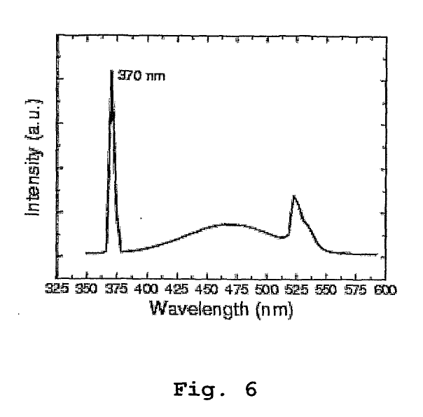

Based on the success in generating both p-type and n-type ZnO by using Zn₃P₂ as the dopant source, a prototype of ZnO p-n homojunction or diode was fabricated and its schematic configuration shown in FIG. 5. An n-type P doped ZnO thin film was grown on the p-type ZnO at room temperature using pure Ar plasma. The I-V curve for a p-n homojunction of ZnO is shown in FIG. 4. During I-V measurements, no luminescence was observed under the forward bias because of the low current level and high defect density in the interface of this starting p-n homojunction. However, a weak UV luminescence was observed at loaded forward bias (20 V) as shown in FIG. 6 at wavelength 525 nm. The strongest peak appear at wavelength 370 nm which corresponds to about 3.349 eV.

A prototype ZnO p-n homojunction or diode is further fabricated using the methods of Examples 1 and 2. The theoretical calculations were performed using a Kohn-Sham density-functional theory (DFT), within a generalized gradient approximation (GGA) using the plane-wave total energy method as implemented in the CASTEP code. In this code, the crystal structures were determined under the condition that the total energy was minimized from all atomic configurations. The self-consistent total energy in the ground state was effectively obtained by the density-mixed scheme. Atomic positions were optimized to minimize the total energy using the quasi-Newton method with the Broyden-Fletcher-Goldfarb-Shanno hessian update scheme (BFGS). Ultrasoft pseudopotentials, were employed to treat “shallow” core electrons as valence states by including multiple sets of occupied states in each angular momentum channel. This leads to high accuracy and transferability of the potentials. The next uppermost states of O (2s, 2p) , P (3s, 3p) and Zn (3d, 4s) were explicitly treated as a part of the valence states, respectively. A 72-atom wurtzite supercell doped with one phosphorus atom was used in the calculation and a 108-atom supercell was also used to confirm the convergence. A plane-wave cut-off of 400 eV was chosen, relaxing all atoms and leaving the lattice constants frozen until the SCF convergence per atom was below 2′10-6 eV. When the charged states were studied, a uniform charge-neutralising background was applied. This approach leads to an error due to the electrostatic interactions between the charge and its images, which was corrected by using Madelung energy.

A Bruker X-Ray Diffraction with Copper (Cu) and Potassium (K) radiation was used to investigate the film crystallinity. The thickness of the deposited films was measured using the optical thin-film measurement system (Filmetrics, F20). Hall effect was performed on HL5500 Hall System at room temperature. I-V characteristic was done on KEITHLEY multimeter. UV luminance was observed using FL WINLAB LS 55.

### Applications

It should be appreciated that the method is not limited to P doped metal oxides but can be used to form other types of doped metal oxides.

It will be appreciated that the doped metal oxides films, particularly P doped ZnO films, resulting from the method are stable and of good reproducibility.

It will be appreciated that the method involves fabricating both an n-type MO film and a p-type MO film to form a p-n junction within the same chamber using the same dopant source simply by varying the amount of oxygen within the chamber.

It will be apparent that various other modifications and adaptations of the invention will be apparent to the person skilled in the art after reading the foregoing disclosure without departing from the spirit and scope of the invention and it is intended that all such modifications and adaptations come within the scope of the appended claims.

1. A method of fabricating a doped metal oxide film comprising the steps of:
(a) providing a semiconductor substrate in a vacuum chamber;
(b) generating plasma comprising at least metal (M), oxygen (O), and dopant ions within said chamber in the presence of an inert carrier gas;
(c) forming a doped metal oxide (MO) film on said substrate from said plasma;
(d) controlling, during step (c), the amount of O ions relative to said metal ions within said plasma to form at least one of an n-type MO film and a p-type MO film on said substrate; and
(e) selecting said dopant that comprises phosphorous (P).

2. A method as claimed in claim 1, wherein said selecting step (e) comprises:
(e1) selecting the dopant that consists essentially of phosphorous (P).

3. A method as claimed in claim 1, further comprising the step of:
(f) selecting said metal ions from Groups IIB or Group III of the Periodic Table of Elements.

4. A method as claimed in claim 3, wherein said selecting step (f) comprises:
(f1) selecting zinc (2n) ions as said metal ions.

5. A method as claimed in claim 1, wherein said controlling step (d) comprises the step of:
(d1) regulating the flow of oxygen gas into said chamber.

6. A method as claimed in claim 1, comprising the step of:
(g) providing a target material within said chamber to generate said at least M, O and dopant ions within said plasma.

7. A method as claimed in claim 6, wherein said providing step (g) comprises the step of:
(g1) selecting a target from at least one of M, MO and dopant material.

8. A method as claimed in claim 6, where said providing step (g) comprises the step of:
(g2) providing one or more target materials within said chamber having a higher molar ratio of M atoms relative to O atoms.

9. A method as claimed in claim 8, where said providing step (g2) comprises selecting the ratio of M atoms relative to O atoms in said target material from the group consisting of: about 1.01:1, about 1.05:1, about 1.1:1, about 1.2:1, about 1.5:1, about 2:1, about 3:1, about 2.01:3, about 2.05:3, about 2.1:3, about 2.2:3, about 2.5:3, about 3:3 and about 4:3.

10. A method as claimed in claim 5, wherein said regulating step (d1) comprises:
(d2) selecting the amount of oxygen gas by volume in the chamber in the range selected from the group consisting of 0% to less than 7%, 0% to 3%, 0% to 2%, 0% to 1%, 3% to 6%, 3% to 5%, and 3% to 4%.

11. A method as claimed in claim 5, wherein said regulating step (d1) comprises:
(d3) maintaining the amount of amount of oxygen within said chamber in the range of 0% to 3% by volume to form the n-type MO film.

12. A method as claimed in claim 5, wherein said regulating step (d1) comprises:
(d4) maintaining the amount of oxygen within said chamber in the range between 3% to less than 7% by volume to form the p-type MO film.

13. A method as claimed in claim 1, comprising the step of maintaining, during step (c), the pressure within said vacuum chamber within the group consisting of: 100 mPa to 7,000 mPa, 100 mPa to 5,000 mPa, 100 mPa to 4,000 mPa, 100 mPa to 3,000 mPa, 100 mPa to 2,000 mPa, 500 mPa to 7,000 mPa, 1000 mPa to 7,000 mPa, 2000 mPa to 7,000 mPa, and 3000 mPa to 7,000 mPa.

14. A method as claimed in claim 1, comprising maintaining the substrate, during step (c), at a temperature in the range selected from the group consisting of: 200° C. to 500° C.; 300° C. to 500° C., 400° C. to 500° C., 200° C. to 400° C., 200° C. to 300° C.

15. A method as claimed in claim 5, wherein the volume ratio of oxygen gas to inert carrier gas in the chamber is in the range selected from the group consisting of: 5:95 to 20:80, 5:95 to 15:85, 5:95 to 10:90, 10:90 to 20:80, and 15:85 to 20:80.

16. A system for fabricating a doped-metal oxide (MO) film comprising:
a vacuum chamber having a mount for mounting a semi-conductor substrate therein;
a plasma generator capable of generating plasma from one or more targets, said plasma comprising at least metal (M), oxygen (O) and dopant ions, wherein said dopant comprises phosphorous;
at least one gas conduit for supplying gas into said chamber;
a controller for controlling the supply of said gas to said chamber and for controlling said plasma generator;
wherein in use, a semi-conductor substrate is mounted on said mount and an inert carrier gas is supplied to said chamber via said gas conduit, and wherein said controller operates said plasma generator to form plasma comprising at least metal (M), oxygen (O) and dopant ions to form a doped MO film layer on said mounted substrate, and wherein the amount of O ions relative to M ions within said plasma is controlled to form at least one of an n-type MO film and a p-type MO film on said substrate.

17. A system as claimed in claim 16, wherein said metal ions are metal ions selected from Groups IIB and III of the Periodic Table of Elements.

18. A system as claimed in claim 17, wherein said metal is zinc (Zn).

19. A system as claimed in claim 16, wherein said dopant consists essentially of phosphorous (P).

20. A system as claimed in claim 16, wherein in use, said controller regulates the flow of oxygen gas into said chamber.

21. A system as claimed in claim 20, wherein the controller comprises a mass flow controller to control said supply of gas into said chamber.

22. A system as claimed in claim 16, wherein said one or more targets comprises at least one of M, dopant and MO.

23. A system as claimed in claim 16, wherein said one or more targets have a higher molar ratio of M atoms relative to O atoms.

24. A system as claimed in claim 16, wherein said one or more targets comprises M atoms relative to O atoms in a ratio selected from the group consisting of: about 1.01:1, about 1.05:1, about 1.1:1, about 1.2:1, about 1.5:1, about 2:1, about 3:1, about 2.01:3, about 2.05:3, about 2.1:3, about 2.2:3, about 2.5:3, about 3:3 and about 4:3.

25. A system as claimed in claim 17, wherein the amount of oxygen gas by volume in the chamber is in the range selected from the group consisting of 0% to less than 7%, 0%, to 3%, 0% to 2%, 0% to 1%, 3% to 6%, 3% to 56%, and 3% to 4%.

26. A system as claimed in claim 17, wherein the amount of amount of oxygen gas by volume within said chamber is maintained in the range of 0% to 3% by volume to form the n-type MO film.

27. A system as claimed in claim 17, wherein the amount of amount of oxygen gas by volume within said chamber is maintained in the range of 3% to less than 7% by volume to form the p-type MO film.

28. A system as claimed in claim 16, wherein pressure within said vacuum chamber is in the range selected from the group consisting of: 100 mPa to 7,000 mPa, 100 mPa to 5,000 mPa, 100 mPa to 4,000 mPa, 100 mPa to 3,000 mPa, 100 mPa to 2,000 mPa, 500 mPa to 7,000 mPa, 1000 mPa to 7,000 mPa, 2000 mPa to 7,000 mPa, and 3000 mPa to 7,000 mPa.

29. A system as claimed in claim 16, wherein temperature within said vacuum chamber is in the range selected from the group consisting of: 200° C. to 500° C., 300° C. to 500° C., 400° C. to 500° C., 200° C. to 400° C., 200° C. to 300° C.

30. A system as claimed in claim 16, wherein the volume ratio of oxygen gas to inert carrier gas in the chamber is in the range selected from the group consisting of: 5:95 to 20:80, 5:95 to 15:85, 5:95 to 10:90, 10:90 to 20:80, and 15:85 to 20:80.

31. A method of fabricating a phosphorous-doped zinc oxide (ZnO) film comprising the steps of:
(a) providing a semiconductor substrate in a vacuum chamber;
(b) generating plasma comprising at least zinc (Zn), oxygen (O) and phosphorous (P) ions within said chamber in the presence of an inert carrier gas;
(c) forming a phosphorous doped ZnO film layer on said substrate from said plasma; and
(d) controlling, during step (c), the amount of O ions relative to Zn ions within said plasma to form at least one of an n-type ZnO film and a p-type ZnO film on said substrate.

32. A method as claimed in claim 31, wherein said controlling step (d) comprises the step of:
(d1) regulating the flow of oxygen gas into said chamber.

33. a method as claimed in claim 31, comprising the step of:
(e) providing a target material within said chamber to generate said at least Zn, O and P ions within said plasma.

34. A method as claimed in claim 33 wherein said providing step (e) comprises the step of:
(e1) selecting a target from at least one of Zn, P, ZnO, P₂O₅, and Zn₃P₂.

35. A method as claimed in claim 33 wherein said providing step (e) comprises the step of:
(e2) providing one or more target materials within said chamber having a higher molar ratio of Zn atoms relative to O atoms.

36. A method as claimed in claim 35 where said providing step (e2) comprises selecting the ratio of Zn atoms relative to O atoms in said target material from the group consisting of: about 1.01:1, about 1.05:1, about 1.1:1, about 1.2:1, about 1.5:1, about 2:1 and about 3:1.

37. A method as claimed in claim 32 wherein said regulating step (d1) comprises:
(d2) selecting the amount of oxygen gas by volume in the chamber in the range selected from the group consisting of 0% to less than 7%, 0% to 3%, 0% to 2%, 0% to 1%, 3% to 6%, 3% to 5%, and 3% to 4%.

38. A method as claimed in claim 32 wherein said regulating step (d1) comprises:
(d3) maintaining the amount of amount of oxygen within said chamber in the range of 0% to 3% by volume to form the n-type ZnO film.

39. A method as claimed in claim 32, wherein said regulating step (d1) comprises:
(d4) maintaining the amount of amount of oxygen within said chamber in the range between 3% to less than 7% by volume to form the p-type ZnO film.

40. A method as claimed in claim 31, comprising the step of maintaining, during step (c), the pressure within said vacuum chamber within the group consisting of: 100 mPa to 7,000 mPa, 100 mPa to 5,000 mPa, 100 mPa to 4,000 mPa, 100 mPa to 3,000 mPa, 100 mPa to 2,000 mPa, 500 mPa to 7,000 mPa, 1000 mPa to 7,000 mPa, 2000 mPa to 7,000 mPa, and 3000 mPa to 7,000 mPa.

41. A method as claimed in claim 31 comprising maintaining the substrate, during step (c), at a temperature in the range selected from the group consisting of: 200° C. to 500° C., 300° C. to 500° C., 400° C. to 500° C., 200° C. to 400° C., 200° C. to 300° C.

42. A method as claimed in claim 32 wherein the volume ratio of oxygen gas to inert carrier gas in the chamber is in the range selected from the group consisting of: 5:95 to 20:80, 5:95 to 15:85, 5:95 to 10:90, 10:90 to 20:80, and 15:85 to 20:80.

43. A system for fabricating a phosphorous doped zinc oxide (ZnO) film comprising:
a vacuum chamber having a mount for mounting a semi-conductor substrate therein;
a plasma generator capable of generating plasma from one or more targets, said plasma comprising at least zinc (Zn), oxygen (O) and phosphorous (P) ions;
at least one gas conduit for supplying gas into said chamber;
a controller for controlling the supply of said gas to said chamber and for controlling said plasma generator;
wherein in use, a semi-conductor substrate is mounted on said mount and an inert carrier gas is supplied to said chamber via said gas conduit, and wherein said controller operates said plasma generator to form plasma comprising at least zinc (Zn), oxygen (O) and phosphorous (P) ions to form a phosphorous doped ZnO film layer on said mounted substrate, and wherein the amount of O ions relative to Zn ions within said plasma is controlled to form at least one of an n-type ZnO film and a p-type ZnO film on said substrate.

44. A system as claimed in claim 43 wherein in use, said controller regulates the flow of oxygen gas into said chamber.

45. A system as claimed in claim 44 wherein the controller comprises a mass flow controller to control said supply of gas into said chamber.

46. A system as claimed in claim 43 wherein said one or more targets comprises at least one of Zn, P, ZnO, P₂O₅, and Zn₃P₂.

47. A system as claimed in claim 43 wherein said one or more targets have a higher molar ratio of Zn atoms relative to O atoms.

48. A system as claimed in claim 43 wherein said one or more targets comprises Zn atoms relative to O atoms in a ratio selected from the group consisting of: about 1.01:1, about 1.05:1, about 1.1:1, about 1.2:1, about 1.5:1, about 2:1 and about 3:1.

49. A system as claimed in claim 44 wherein the amount of oxygen gas by volume in the chamber is in the range selected from the group consisting of 0% to less than 7%, 0% to 3%, 0% to 2%, 0% to 1%, 3% to 6%, 3% to 5%, and 3% to 4%.

50. A system as claimed in claim 44, wherein the amount of amount of oxygen gas by volume within said chamber is maintained in the range of 0% to 3% by volume to form the n-type ZnO film.

51. A system as claimed in claim 44, wherein the amount of amount of oxygen gas by volume within said chamber is maintained in the range of 3% to less than 7% by volume to form the p-type ZnO film.

52. A system as claimed in claim 43 wherein pressure within said vacuum chamber is in the range selected from the group consisting of: 100 mPa to 7,000 mPa, 100 mPa to 5,000 mPa, 100 mPa to 4,000 mPa, 100 mPa to 3,000 mPa, 100 mPa to 2,000 mPa, 500 mPa to 7,000 mPa, 1000 mPa to 7,000 mPa, 2000 mPa to 7,000 mPa, and 3000 mPa to 7,000 mPa.

53. A system as claimed in claim 43 wherein temperature within said vacuum chamber is in the range selected from the group consisting of: 200° C. to 500° C., 300° C. to 500° C., 400° C. to 500° C., 200° C., to 400° C., 200° C. to 300° C.

54. A system as claimed in claim 43, wherein the volume ratio of oxygen gas to inert carrier gas in the chamber is in the range selected from the group consisting of: 5:95 to 20:80, 5:95 to 15:85, 5:95 to 10:90, 10:90 to 20:80, and 15:85 to 20:80.
